(19) United States
(12) Patent Application Publication
(10) Pub. No.: US 2026/0052680 A1
(43) Pub. Date: Feb. 19, 2026

(54) SEMICONDUCTOR INTEGRATED CIRCUIT DEVICE

(71) Applicant: SK hynix Inc., Icheon-si Gyeonggi-do (KR)

(72) Inventor: Young Min KIM, Icheon-si Gyeonggi-do (KR)

(73) Assignee: SK hynix Inc., Icheon-si Gyeonggi-do (KR)

(21) Appl. No.: 19/022,151

(22) Filed: Jan. 15, 2025

(30) Foreign Application Priority Data
Aug. 13, 2024 (KR) 10-2024-0108238

(51) Int. Cl. H10B 12/00; G11C 11/4091

(52) U.S. Cl. CPC H10B 12/50; G11C 11/4091

(57) ABSTRACT

A semiconductor integrated circuit device includes a first memory cell array and a second memory cell array each including a plurality of word lines extending in a first direction, a plurality of bit lines extending in a second direction perpendicular to the first direction, and a plurality of memory cells connected between the plurality of word lines and the plurality of bit lines; a first switch configured to selectively connect a first plurality of sense amplifiers that are connected to bit lines among the plurality of bit lines of the first memory cell array with data input/output (I/O) lines; and a second switch configured to selectively connect a second plurality of sense amplifiers that are connected to bit lines of the plurality of bit lines of the second memory cell array with the data I/O lines; wherein the first memory cell array and the second memory cell array are spaced apart in the first direction; and wherein the first switch is rotated 180 degrees with respect to the second switch.

### CROSS-REFERENCE TO RELATED APPLICATION

The present application claims priority under 35 U.S.C. § 119(a) to Korean patent application number 10-2024-0108238, filed on Aug. 13, 2024, in the Korean Intellectual Property Office, which application is incorporated herein by reference in its entirety.

### BACKGROUND

### 1. Technical Field

The present disclosure relates to a semiconductor integrated circuit device, including but not limited to a structure of a semiconductor memory device.

### 2. Related Art

A typical semiconductor memory device includes a plurality of memory cell arrays. Each of the memory cell arrays includes a plurality of word lines, a plurality of bit lines and a plurality of memory cells connected between the plurality of word lines and the plurality of bit lines.

The semiconductor memory device includes a plurality of input and output signal lines configured to write data to the memory cell array and/or to read data stored in the memory cell array to facilitate data exchange with a device external to the semiconductor device.

As integration density of the semiconductor memory device increases, input/output (I/O) lines may be organized hierarchically between bit lines to global bit lines using a multi-wiring structure.

In order to form the hierarchical I/O lines, at least one contact and at least one contact pad between lower and upper wiring may be required.

### SUMMARY

According to an embodiment, a semiconductor integrated circuit device may include a first memory cell array and a second memory cell array each including a plurality of word lines extending in a first direction, a plurality of bit lines extending in a second direction perpendicular to the first direction, and a plurality of memory cells connected between the plurality of word lines and the plurality of bit lines; a first switch configured to selectively connect a first plurality of sense amplifiers that are connected to bit lines among the plurality of bit lines of the first memory cell array with data input/output (I/O) lines; and a second switch configured to selectively connect a second plurality of sense amplifiers that are connected to bit lines of the plurality of bit lines of the second memory cell array with the data I/O lines; wherein the first memory cell array and the second memory cell array are spaced apart in the first direction; and wherein the first switch is rotated 180 degrees with respect to the second switch.

According to an embodiment, a semiconductor integrated circuit device may include a first memory cell array, a second memory cell array, a third memory cell array, and a fourth memory cell array arranged in a matrix in a first direction and a second direction; a first selection block arranged between the first memory cell array and the third memory cell array arranged consecutively in the second direction; and a second selection block arranged between the second memory cell array and the fourth memory cell array arranged consecutively in the second direction; wherein the first selection block comprises a plurality of sense amplifiers connecting a first subset of bit lines of the first memory cell array with a first subset of bit lines of the third memory cell array, and a first switch including a plurality of selection transistors connected to the plurality of sense amplifiers that transmit a signal from a bit line selected from the first memory cell array and the third memory cell array to one of a plurality of input and output signal lines in response to a selection signal; wherein the second selection block comprises a plurality of sense amplifiers connecting a first subset of bit lines of the second memory cell array with a first subset of bit lines of the fourth memory cell array, and a second switch including a plurality of selection transistors, the plurality of selection transistors connected to the plurality of sense amplifiers to transmit a signal from a bit line selected from the second memory cell array and the fourth memory cell array to one of a plurality of input/output lines in response to a selection signal; and wherein the plurality of selection transistors of the first switch is rotated 180 degrees with respect to the plurality of selection transistors of the second switch.

According to an embodiment, a semiconductor integrated circuit device may include a plurality of switches, each of the switches including a plurality of selection transistors configured to selectively connect a plurality of sense amplifiers that are connected to a plurality of bit lines with a plurality of data input/output lines based on selection signals; wherein the plurality of selection transistors of a first switch is rotated 180 degrees with respect to the plurality of selection transistors of a second switch, and the plurality of selection transistors of the first switch is spaced apart from the plurality of selection transistors of the second switch in a first direction.

### BRIEF DESCRIPTION OF THE DRAWINGS

FIG. 1 is a block diagram illustrating a semiconductor memory device in accordance with an embodiment of the present disclosure;

FIG. 2 is a circuit diagram illustrating a column selection block of a semiconductor memory device in accordance with an embodiment of the present disclosure;

FIG. 3 is a plan view illustrating a column switching transistor in a column switch of a semiconductor memory device in accordance with an embodiment of the present disclosure;

FIG. 4 is a plan view illustrating a wiring structure of a column switch of a semiconductor memory device in accordance with an embodiment of the present disclosure;

FIG. 5 is a plan view illustrating a wiring structure of a column switch of a semiconductor memory device in accordance with an embodiment of the present disclosure;

FIG. 6 is a circuit diagram illustrating a configuration of a semiconductor memory device including a sense amplifier in accordance with an embodiment of the present disclosure; and

FIG. 7 is a cross-sectional view taken along a line A-A′ of FIG. 4 in accordance with an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

Terms such as “vertical,” “horizontal,” “top,” “under,” “over,” “on,” “side,” “upper,” “lower,” “left,” “right,” “column,” “row,” and other terms implying relative spatial relationship or orientation are utilized only for the purpose of ease of description or reference to a drawing and are not otherwise limiting. For example, descriptions related to rows may be applicable to columns, and descriptions related to columns may be applicable to rows. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

When one element is identified as “connected” to another element, the elements may be connected directly or through an intervening element between the elements. When two elements are identified as “directly connected,” one element is directly connected to the other element without an intervening element between the two elements.

A plurality of dummy patterns and dummy bit lines between circuit blocks, such as between column switching elements and memory cell arrays, may provide contact and contact pad areas, as well as maintain a sufficient distance between sequential contacts and sequential contact pads. Improved integration density for a semiconductor integrated circuit device may be achieved by reducing a quantity of dummy patterns as described in the present disclosure.

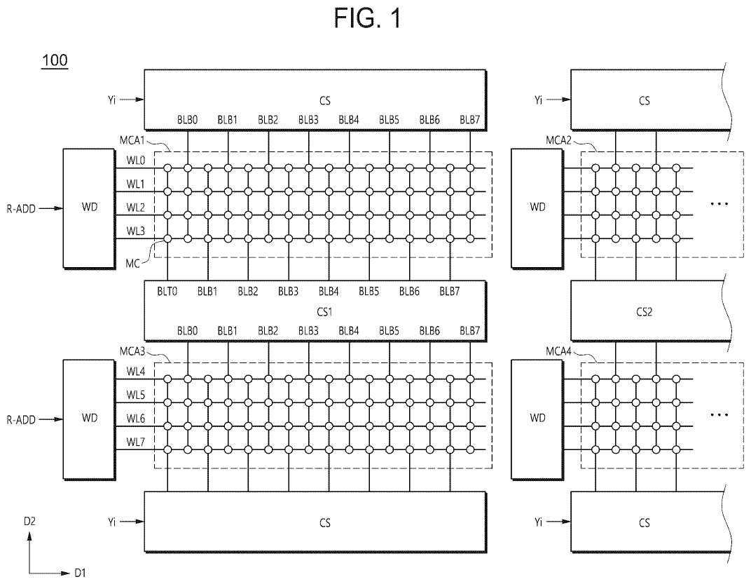

FIG. 1 is a block diagram illustrating a semiconductor memory device in accordance with an embodiment.

Referring to FIG. 1, a semiconductor memory device 100 includes a plurality of memory cell arrays, such as first memory cell MCA1, a second memory cell MCA2, a third memory cell MCA3, and a fourth memory cell array MCA4. The memory cell arrays MCA1 through MCA4 may be arranged in a matrix, for example. In an embodiment, the first memory cell array MCA1 and the second memory cell array MCA2 are arranged side-by-side in a row direction D1. The third memory cell array MCA3 and the fourth memory cell array MCA4 are arranged side-by-side in the row direction D1. The first memory cell array MCA1 and the third memory cell array MCA3 are arranged side-by-side in a column direction D2. The second memory cell array MCA2 and the fourth memory cell array MCA4 are arranged side-by-side in the column direction D2. Side-by-side does not imply touching.

The memory cell arrays MCA1 through MCA4 include, for example, a zeroth word line WL0, a first word line WL1, a second word line, WL2, and a third word line WL3 extending in parallel in the row direction D1, and a zeroth to seventh bit line BLT0 through BLT7 and BLB0 through BLB7 extending in parallel in the column direction D2.

For example, a memory cell MC is connected at an intersection of the word lines WL0 through WL3 and the bit lines BLT0 through BLT7 and BLB0 through BLB7. The memory cell arrays MCA1, MCA2, MCA3, and MCA4 may be disposed in various different arrangements, for example, in a folded symmetrical structure.

For example, each memory cell MC may include a storage element (not shown). Alternately, each memory cell MC may include a switch (not shown) and a storage element.

The semiconductor memory device 100 includes a row selection block WD and a column selection block CS configured to control the plurality of memory cell arrays MCA1 through MCA4.

For example, the row selection block WD is located between consecutive memory cell arrays in the row direction D1.

The row selection block WD select one of the word lines WL0 through WL3 by decoding a row address R-ADD in an active mode. The row selection block WD disables the unselected word lines WL0 through WL3.

The column selection block CS control bit lines of the memory cell arrays MCA1 through MCA4. For example, the column selection block CS selects bit lines of consecutive memory cell arrays in the column direction D2. The column selection block CS senses data stored in the selected bit lines or store data in the selected bit lines. The column selection block may be referred to simply as selection block, such as a first selection block and a second selection block, and need not associate with a column.

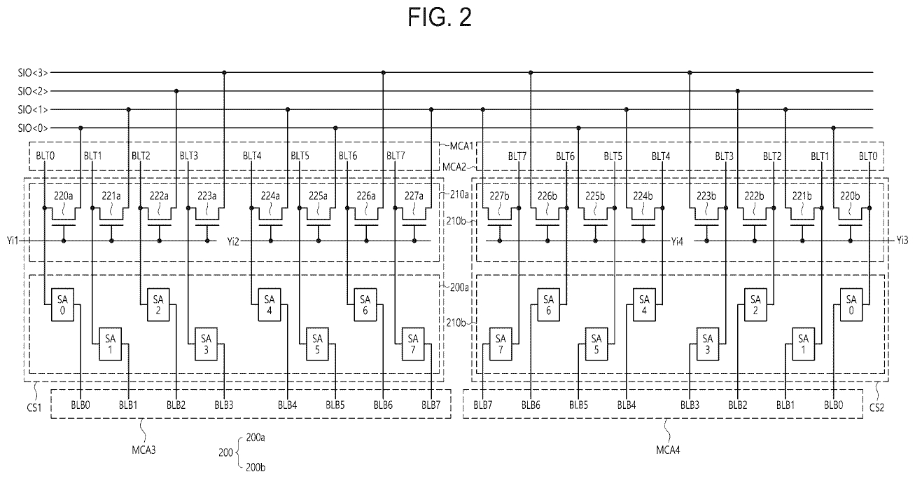

FIG. 2 is a circuit diagram illustrating a column selection block in accordance with an embodiment.

Referring to FIG. 1 and FIG. 2, a first column selection block CS1 includes a first sense amplifier array 200a and a first column switch 210a. A second column selection block CS2 is located consecutively with the first column selection block CS1 in the row direction D1. The second column selection block CS2 includes a second sense amplifier array 200b and a second column switch 210b. The column switches may be referred to simply as switches, such as a first switch and a second switch, and need not associate with a column.

In the example of FIG. 2, the first sense amplifier array 200a includes a plurality of sense amplifiers SA0 through SA7. A first subset of the plurality of sense amplifiers of the first sense amplifier array 200a is connected with a first subset of bit lines BLT0 through BLT3 and BLB0 through BLB3 among a plurality of bit lines BLT0 through BLT7 of the first memory cell array MCA1 and a plurality of bit lines BLB0 through BLB7 of the third memory cell array MCA3. A second subset of the plurality of sense amplifiers of the first sense amplifier array 200a is connected with a second subset of bit lines BLT4 through BLT7 and BLB4 through BLB7 among a plurality of bit lines BLT0 through BLT7 of the first memory cell array MCA1 and a plurality of bit lines BLB0 through BLB7 of the third memory cell array MCA3.

In the example of FIG. 2, the second sense amplifier array 200b includes a plurality of sense amplifiers SA0 through SA7. A first subset of the plurality of sense amplifiers of the second sense amplifier array 200b is connected with a first subset of bit lines BLT0 through BLT3 and BLB0 through BLB3 among a plurality of bit lines BLT0 through BLT7 of the second memory cell array MCA2 and a plurality of bit lines BLB0 through BLB7 of the fourth memory cell array MCA4. A second subset of the plurality of sense amplifiers of the second sense amplifier array 200b is connected with a second subset of bit lines BLT4 through BLT7 and BLB4 through BLB7 among a plurality of bit lines BLT0 through BLT7 of the second memory cell array MCA2 and a plurality of bit lines BLB0 through BLB7 of the fourth memory cell array MCA4.

For example, each of the sense amplifier arrays 200a and 200b includes a zeroth sense amplifier SA0 to a seventh sense amplifier SA7. The sense amplifiers SA0 through SA7 are connected to the bit lines BLT0 through BLT7 and BLB0 through BLB7 of the memory cell arrays MCA1, MCA3, MCA2, and MCA4 arranged consecutively in the column direction D2 to sense and amplify data in the selected memory cells MC.

Although FIG. 2 illustrates an example of a correspondence between different subsets of bit lines of memory cell arrays and subsets of sense amplifiers, various other correspondences between bit lines of memory cell arrays and sense amplifiers may be utilized. For example, the sense amplifiers SA0 through SA7 of the first sense amplifier array 200a may be connected with the bit lines BLT0 through BLT7 of the first memory cell array MCA1 and the bit line bars BLB0 through BLB7 of the third memory cell array MCA3, respectively. Another example of correspondence includes electrically connecting odd-numbered sense amplifiers SA1, SA03, SA05, and SA07 of the first sense amplifier array 200a with odd-numbered bit lines BLT1, BLT3, BLT5, and BLT7 of the first memory cell array MCA1 and odd-numbered bit line bars BLB1, BLB3, BLB5, and BLB7 of the third memory cell array MCA3. Another example of correspondence includes electrically connecting even-numbered sense amplifiers SA0, SA02, SA04, and SA06 of the first sense amplifier array 200a with even-numbered bit lines BLT0, BLT2, BLT4, and BLT6 of the first memory cell array MCA1 and even-numbered bit line bars BLB0, BLB2, BLB4, and BLB6 of the third memory cell array MCA3.

Although the embodiment of FIG. 2 illustrates the first sense amplifier array 200a, each sense amplifier array may be configured with the same structure and may utilize the same correspondence between the bit lines and the sense amplifiers.

The first column switch 210a includes a plurality of column selection transistors, such as a zeroth column selection transistor 220a, a first column selection transistor 221a, a second column selection transistor 222a, a third column selection transistor 223a, a fourth column selection transistor 224a, a fifth column selection transistor 225a, a sixth column selection transistor 226a, and a seventh column selection transistor 227a, and the second column switch 210b includes a plurality of column selection transistors, such as a zeroth column selection transistor 220b, a first column selection transistor 221b, a second column selection transistor 222b, a third column selection transistor 223b, a fourth column selection transistor 224b, a fifth column selection transistor 225b, a sixth column selection transistor 226b, and a seventh column selection transistor 227b. The column selection transistors may be referred to simply as selection transistors, such as a first selection transistor and a second selection transistor, and need not associate with a column.

Because circuit structures of the column switches 210a and 210b are substantially the same, the first column switch 210a is described as an example.

In response to column selection signals Yi1 and Yi2, the column selection transistors 220a through 227a selectively and electrically connect one of the bit lines BLT0 through BLT7, connected with one of the sense amplifiers SA0 through SA7, with one data I/O lines, such as a plurality of segment I/O lines SIO<0:3>. The first column switches 210a may include NMOS transistors. In an embodiment, the plurality of segment I/O lines SIO<0:3> may be multilayer interconnection wiring located over the first column switch 210a. The column selection signals may be referred to simply as selection signals, such as a first selection signal, a second selection signal, and so forth, and need not associate with a column.

A sense amplifier connected with a selected bit line senses and amplifies data stored at the selected bit line. The column select signal Yi1 or Yi2 is enabled such that a column selection transistor connected with the selected bit line is turned on. The amplified data at the selected bit line is transmitted to one of the segment I/O lines (SIO<0:3>) via the column selection transistor. For example, a column select signal may simultaneously control, for example, four column selection transistors.

For example, a first subset of the column selection transistors 220a through 223a of the first switch 210a receives the first column selection signal Yi1 as a common gate signal. A second subset of column selection transistors 224a through 227a of the first column switch 210a receives the second column selection signal Yi2 as a common gate signal. The first subset of column selection transistors 220b through 223b of the second switch 210b receives a third column selection signal Yi3 as a common gate signal. The second subset of column selection transistors 224b through 227b of the second switch 210b receives a fourth column selection signal Yi4 as a common gate signal. The column selection signals Yi1 through Yi4 may be enabled at different times. Accordingly, data at bit lines selected from the bit lines BLT0 through BLT3 of the first memory cell array MCA1, data at bit lines selected from the bit lines BLT4 through BLT7 of the first memory cell array MCA1, data at bit lines selected from the bit lines BLT0 through BLT3 of the second memory cell array MCA2, and data at bit lines selected from the bit lines BLT4 through BLT7 of the second memory cell array MCA2 are selectively transmitted on the segment I/O lines SIO<0:3>.

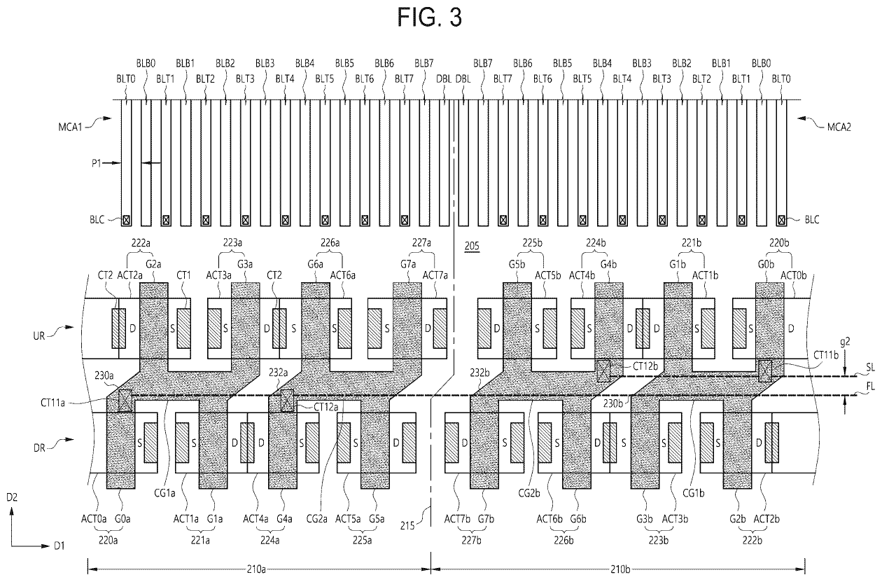

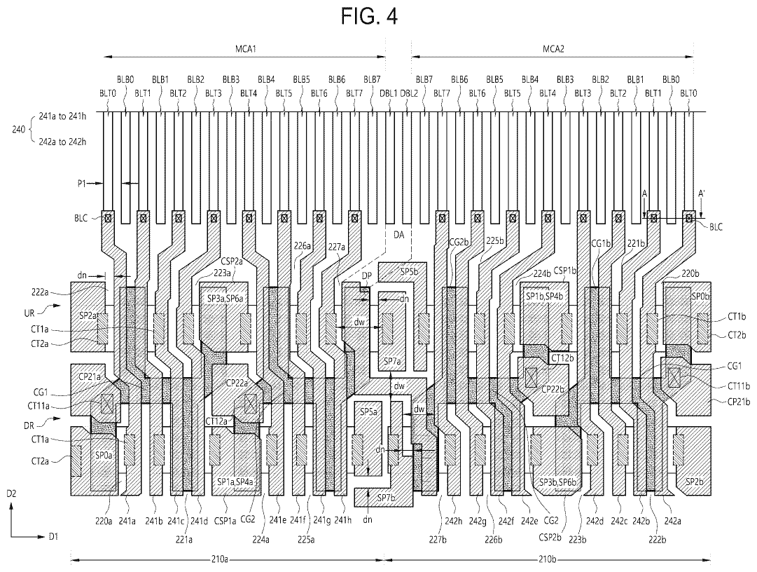

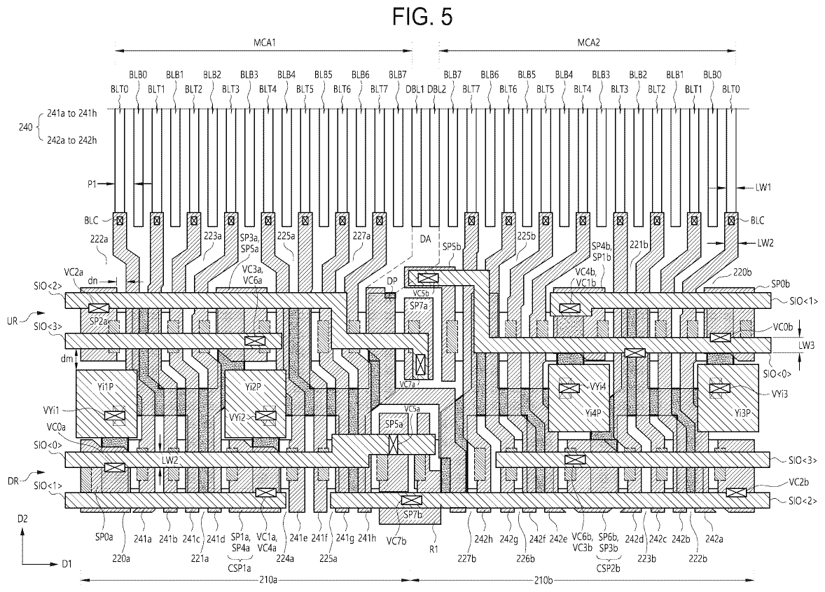

FIG. 3 is a plan view illustrating a column switching transistor of a column switch in accordance with an embodiment. FIG. 4 is a plan view illustrating a first wiring structure of a column switch in accordance with an embodiment. FIG. 5 is a plan view illustrating a second wiring structure of a column switch in accordance with an embodiment.

For reference, FIG. 3 to FIG. 5 illustrate plan views of the column switches 210a and 210b in FIG. 2.

Referring to FIG. 3, a zeroth active region ACT0a to a seventh active region ACT7a in which the column selection transistors 220a through 227a are formed, respectively, on a semiconductor substrate (not shown) in an area for the first column switch 210a, and a zeroth active region ACT0b to a seventh active region ACT7b in which the column selection transistors 220b through 227b are formed, respectively, on the semiconductor substrate in an area for the second column switch 210b. For example, the active regions ACT0a through ACT7a and ACT0b through ACT7b are formed on an isolation layer 205 on the semiconductor substrate.

To efficiently arrange the active regions ACT0a through ACT7a and ACT0b through ACT7b, the zeroth active region ACT0a, the first active region ACT1a, the fourth active region ACT4a, and the fifth active region ACT5a of the first column switch 210a are arranged in a lower row DR. The second active region ACT2a, the third active region ACT3a, the sixth active region ACT6a, and the seventh active region ACT7a of the first column switch 210a are arranged in the upper row UR.

In an embodiment, the upper row UR and the lower row DR are located on the same or one plane, for example, on a surface of the semiconductor substrate. For example, the upper row UR is located closer to the memory cell arrays MCA1 and MCA2 than to the memory cell arrays MCA3 and MCA4. The lower row DR is located closer to the memory cell arrays MCA1 and MCA2 than to the memory cell arrays MCA3 and MCA4.

The active regions ACT0a through ACT7a of the first column switch 210a are rotated 180 degrees with respect to the zeroth to seventh active regions ACT0b through ACT7b of the second column switch 210b.

For example, the second column switch 210b is rotated 180 degrees with respect to the first column switch 210a. The seventh active region ACT7b, the sixth active region ACT6b, the third active region ACT3b, and the second active region ACT2b are arranged sequentially from a boundary line 215 in the row direction D1 in the lower row DR of the second column switch 210b. The fifth active region ACT5b, the fourth active region ACT4b, the first active region ACT1b, and the zeroth active region ACT0b are arranged sequentially from the boundary line 215 in the row direction D1 in the upper row DR of the second column switch 210b.

The active regions ACT0a through ACT7a and ACT0b through ACT7b have a long axis extending in the row direction D1, for example. The active regions ACT0a through ACT7a and ACT0b through ACT7b are illustrated as a rectangular structure with a long axis in the row direction D1, but are not limited to this example.

In an embodiment, for example to improve arrangement efficiency, the active regions ACT2a, ACT3a, ACT6a, and ACT7a arranged in the upper row UR of the first column switch 210a are shifted in the row direction D1 such that the active regions ACT2a, ACT3a, ACT6a, and ACT7a are offset in the row direction D1 from the active regions ACT0a, ACT1a, ACT4a and ACT5a arranged in the lower row DR of the first column switch 210a.

The active regions ACT5b, ACT4b, ACT1b and ACT0b arranged in the upper row UR of the second column switch 210b are shifted in the row direction D1 such that the active regions ACT5b, ACT4b, ACT1b, and ACT0b are offset in the row direction D1 from the active regions ACT7b, ACT6b, ACT3b, and ACT2b arranged in the lower row DR.

A zeroth column selection gate G0a through a seventh column selection gate G7a and zeroth column selection gate G0b through seventh column selection gate G7b are arranged over the active regions ACT0a through ACT7a of the first column switch 210a and active regions ACT0b through ACT7b of the second column switch 210b in the column direction D2, respectively. For example, each of the column selection gates G0a through G7a and G0a through G7b extend in the column direction D2 at a center of the active regions ACT0a through ACT7a and ACT0b through ACT7b, respectively. The column selection gates ACT0a through ACT7a and ACT0b through ACT7b may include a conductive material, such as, a polysilicon layer including conductive impurities. Although not shown, a gate insulation layer (not shown) may be interposed between the column selection gates G0a through G7a and G0a through G7b and the active regions ACT0a through ACT7a and ACT0b through ACT7b. The column selection gates may be referred to simply as selection gates, such as a first selection gate and a second selection gate, and need not associate with a column.

The column selection gates G0a through G3a and G0b through G3b among the column selection gates G0a through G7a and G0a through G7b are interconnected by first connection patterns 230a and 230b to form first common gates CG1a and CG1b. The column selection gates G4a through G7a and G4b through G7b among the column selection gates G0a through G7a and G0a through G7b are interconnected by second connection patterns 232a and 232b to form second common gates CG2a and CG2b. For example, the first connection pattern 230a and 230b and the second connection pattern 232a and 232b are located between the lower row DR and the upper row UR.

Conductive impurities may be implanted in the zeroth to seventh active regions ACT0a through ACT7a and ACT0b through ACT7b at both sides of the zeroth to seventh column selection gates G0a through G7a and G0a through G7b. For example, the conductive impurity may include n-type impurities, such as Arsenic (As) or Phosphorus (P). Accordingly, a source S and a drain D may be formed in the zeroth to seventh active regions ACT0a through ACT7a and ACT0b through ACT7b at both sides of the zeroth to seventh column selection gates (G0a through G7a, G0a through G7b), respectively. Thus, the zeroth to seventh column selection transistors 220a through 227a may be formed in the first column switch 210a, and the zeroth to seventh column selection transistors 220b through 227b may be formed in the second column switch 210b.

In an embodiment, the active regions ACT0a through ACT3a and ACT0b through ACT3b are controlled by the first common gates CG1a and CG1b, respectively, and are separated by the isolation layer 205. The active regions ACT4a through ACT7a and ACT4b through ACT7b are controlled by the second common gates CG2a and CG2b, respectively, and are separated by the isolation layer 205.

The active regions, such as the first active regions ACT1a and ACT1b and the fourth active regions ACT4a and ACT4b, which are controlled by different common gates CG1a, CG2a and CG1b, CG2b, are arranged consecutively in the same row and may partially share drain regions with one another. The third active region ACT3a and ACT3b and the sixth active region ACT6a and ACT6b may partially share drain regions with each other.

For example, the first column selection transistor 221a and the fourth column selection transistors 224a share one drain D in the first column switch 210a. The third column selection transistor 223a and the sixth column selection transistor 226a share one drain D in the first column switch 210a.

The first column selection transistor 221b and the fourth column selection transistors 224b share one drain D in the second column switch 210b. The third column selection transistors 223a and the sixth column selection transistors 226a share one drain D in the second column switch 210b.

In an embodiment, when the column switches 210a and 210b and the memory cell arrays MCA1 and MCA2 are integrated on the same semiconductor substrate, the column selection transistors 220a through 227a and 220b through 227b may be simultaneously formed with the cell transistors (not shown) that are the switches (not shown) of the memory cell arrays MCA1 and MCA2.

Alternatively, when the column switches 210a and 210b and the memory cell arrays MCA1 and MCA2 are integrated on different semiconductor substrates, the column selection transistors 220a through 227a and 220b through 227b may be formed by a process different from a process that forms the cell transistors (not shown) of the memory cell arrays MCA1 and MCA2.

In an embodiment, the column selection transistors 220a through 223a and 220b through 223b are controlled by the first common gates CG1a and CG1b, respectively, are divided into upper rows UR and lower rows DR, and are arranged, for example, based on a length and an area of the first connection patterns 230a and 230b. The column selection transistors 224a through 227a and 224b through 227b are controlled by the second common gates CG2a and CG2b, respectively, are divided into upper rows UR and lower rows DR, and are arranged, for example, based on a length and an area of the second connection patterns 232a and 232b.

A first insulating layer (not shown) is formed on a semiconductor substrate (not shown) on which the column selection transistors 220a through 227a and 220b through 227b of the column switches 210a and 210b are formed.

First contact plugs CT1a, CT1b and second contact plugs CT2a and CT2b contact the sources S and the drains D of the column selection transistors 220a through 227a and 220b through 227b, respectively, and are formed, for example, on the first insulating interlayer. The contact plugs CT1a, CT1b, CT2a, and CT2b are isolated from the nearest column selection gates G0a through G7a and G0a through G7b.

A plurality of bit lines BLT0 through BLT7 and BLB0 through BLB7 are arranged on the first insulating layer over the memory cell arrays MCA1 and MCA2. The plurality of bit lines BLT0 through BLT7 and BLB0 through BLB7 may include a conductive material. The plurality of bit lines BLT0 through BLT7 and BLB0 through BLB7 may be arranged, for example, such that bit lines BLT, BLT0 through BLT7, alternate with bit line bars BLB, BLB0 through BLB7. The plurality of bit lines are arranged with a first pitch P1.

In an embodiment, the plurality of bit lines BLT0 through BLT7 and BLB0 through BLB7 of the first memory cell array MCA1 and the plurality of bit lines BLT0 through BLT7 and BLB0 through BLB7 of the second memory cell array MCA2 are arranged in the row direction D1 are arranged in a sequence that is symmetrically folded with respect to a midpoint between the first memory cell array MCA1 and the second memory cell array MCA2.

A second insulating layer (not shown) is formed on the first insulating layer on which the bit lines BLT0 through BLT7 and BLB0 through BLB7 are formed.

For example, a plurality of bit line contacts BLC are formed on the second insulating layer. Each of plurality of bit line contacts BLC contacts a different one of the bit lines BLT0 through BLT7 and BLB0 through BLB7.

For example, the bit line contacts BLC are formed at first ends of the bit lines BLT0 through BLT7 and second ends of the bit line bars BLB0 through BLB7. For example, the first ends of the bit lines BLT0 through BLT7 and BLB0 through BLB7 are located closer to the column switches 210a and 210b in the column direction D2, and are located between the second ends of the bit lines BLT0 through BLT7 and BLB0 through BLB7 and the column switches 210a and 210b. The second ends of the bit lines BLT0 through BLT7 and BLB0 through BLB7 are located further away from the column switches 210a and 210b than the first ends of the bit lines BLT0 through BLT7 and BLB0 through BLB7 in the column direction D2.

A first common gate contact CT11a and CT11b and a second common gate contact CT12a and CT12b are disposed, for example, within the second insulating layer and the first insulating layer.

The first common gate contact CT11a of the first column switch 210a extends through the second insulating layer and the first insulating layer and contacts the first common gate CG1a of the first column switch 210a. In an embodiment, the first common gate contact CT11a is arranged at a first side, for example, a left side, of the first connection pattern 230a of the first common gate CG1a.

The first common gate contact CT11b of the second column switch 210b extends through the second insulating layer and the first insulating layer and contacts the first common gate CG1b of the second column switch 210b. In an embodiment, the second common gate contact CT11b is arranged on a second side, for example, a right side, of the first connection pattern 230b of the first common gate CG1b.

For example, the first common gate contact CT11a of the first column switch 210a is rotated 180 degrees with respect to the first common gate contact CT11b of the second column switch 210b.

In an embodiment, the first common gate contact CT11a of the first column switch 210a is offset from the first common gate contact CT11b of the second column switch 210b in the second direction D2. The first common gate contact CT11a of the first column switch 210a is arranged close to the lower row DR, and the first common gate contact CT11b of the second column switch 210b is arranged close to the upper row UR.

The second common gate contact CT12a of the first column switch 210a extends through the second insulating layer and the first insulating layer and contacts the second common gate CG2a of the first column switch 210a. In an embodiment, the second common gate contact CT12a is arranged on the first side, for example, a left side, of the second connection pattern 232a of the second common gate CG2a. The second common gate contact CT12b of the second column switch 210b extends through the second insulating layer and the first insulating layer and contacts the second common gate CG2b of the second column switch 210b. In an embodiment, the second common gate contact CT12b is arranged on the second side, for example, the right side, of the second connection pattern 232b of the second common gate CG2b. For example, the second common gate contact CT12a of the first column switch 210a is rotated 180 degrees with respect to the second common gate contact CT12b of the second column switch 210b.

In an embodiment, the second common gate contact CT12a of the first column switch 210a is offset from the second common gate contact CT12b of the second column switch 210b in the second direction D2. The second common gate contact CT12a of the first column switch 210a is arranged closer to the lower row DR, and the second common gate contact CT12b of the second column switch 210b is arranged closer to the upper row UR.

For example, the first common gate contact CT11a is located in a first straight line FL with respect to the second common gate contact CT12a of the first column switch 210a in the first direction D1. The first common gate contact CT11b is located in a second straight line SL with respect to the second common gate contact CT12b of the second column switch 210b in the first direction D1. The first straight line FL and the second straight line SL are parallel in the first direction D1 and separated by a gap g2 in the second direction D2.

Because the column selection transistors 220a through 227a of the first column switch 210a are rotated 180 degrees with respect to the column selection transistors 220b through 227b of the second column switch 210b, and because the contacts CT11a and CT12a of the first column switch 210a are rotated 180 degrees with respect to the contacts CT11b and CT12b of the second column switch 210b, a distance D2, such as shown in FIG. 3, between the common gate contacts CT11a and CT12a of the first column switch 210a and between the common gate contacts CT11b and CT12b of the second column switch 210b is established in the first direction D1.

The second common gate contact CT12a of the first column switch 210a and the second common gate contact CT12b of the second column switch 220a may be spaced apart in the first direction D1 by a distance greater than twice the length of the second connection pattern 232b.

Conventional column switches typically have the same shape and orientation and are repeatedly arranged. As a result, each of the common gate contacts are located at the same side of the column switches and causing difficulty with implementation of sufficient spacing between the common gate contacts. To resolve this issue, a dummy gate may be formed at the boundary between the first column switch and the second column switch. A dummy gate between the first column switch and the second column switch, however, at least four dummy bit lines may be formed between memory cell arrays to facilitate the dummy gate, which causes a reduction in an integration density of semiconductor memory devices.

According to an embodiment, by rotating the column selection transistors 220a through 227a and the common gate contacts CG1a and CG2a of the first column switch 210a by 180 degrees with respect to column selection transistors 220b through 227b and the common gate contacts CG1b and CG2b of the second column switch 210b, a sufficient distance may be provided between the common gate contacts CG1a, CG2a, CG1b, and CG2b, such that forming a separate dummy gate is avoided. For example, the column selection transistors 220a through 227a may be arranged to be diagonally symmetrical with the column selection transistors 220b through 227b.

Referring to FIG. 3 and FIG. 4, a first wiring structure is formed on the second insulating layer. For example, the first wiring structure includes first column gate pads CP21a and CP21b, second column gate pads CP22a and CP22b, sense amplifier pads SP0a through SP7a and SP0b through SP7b and a sub-pattern 240. The column gate pads may be referred to simply as gate pads, such as a first gate pad and a second gate pad, and need not be associated with a column.

The first column gate pads CP21a and CP21b, the second column gate pads CP22a and CP22b, the sense amplifier pads SP0a through SP7a and SP0b through SP7b, and the sub-pattern 240 may be formed from the same metal film.

The first column gate pads CP21a and CP21b electrically contact the first common gate contact CT11a and CT11b, respectively. The first column gate pads CP21a and CP21b are formed having a larger area than the area of the first common gate contacts CT11a and CT11b.

The second column gate pads CP22a and CP22b electrically contact the second common gate contacts CT12a and CT12b, respectively. The second column gate pads CP22a and CP22b are formed having a larger area than the area of the second common gate contacts CT12a and CT12b.

The column gate pads CP21a, CP21b, CP22a, and CP22b are formed with sufficient contact area for column select signal lines (not shown) to be formed on the column gate pads CP21a, CP21b, CP22a, and CP22b.

The sense amplifier pads SP0a through SP7a of the first column switch 210a are electrically connected with the drains D of the column selection transistors 220a through 227a, respectively, via the second contact plugs CT2a. The sense amplifier pads SP0b through SP7b of the second column switch 210b are electrically connected with the drains D of the column selection transistors 220b through 227b, respectively, via the second contact plugs CT2b.

Because the first column selection transistor 221a and the fourth column selection transistor 224a of the first column switch 210a share one drain D, the first common sense amplifier pad CSP1a functions as the first sense amplifier pad SP1a and the fourth sense amplifier pad SP4a. Because the first column selection transistor 221b and the fourth column selection transistor 224b of the second column switch 210b share one drain D, the first common sense amplifier pad CSP1b functions as the first sense amplifier pads SP1b and the fourth sense amplifier padSP4b. The first common sense amplifier pads CSP1a and CSP1b are selectively operated as the first sense amplifier pads SP1a and SP1b or the fourth sense amplifier pads SP4a and SP4b depending on a voltage applied to the first common gates CG1a and CG1b and the second common gates CG2a and CG2b.

Because the third and sixth column selection transistors 223a and 226a of the first column switch 210a share one drain D, and the third and sixth column selection transistors 223b and 226b of the second column switch 220b share one drain D, the second common sense amplifier pads CSP2a and CSP2b corresponding to the third sense amplifier pads SP3a and SP3b and the sixth sense amplifier pads SP6a and SP6b are formed on the common drains D of the third column selection transistors 223a and 223b and the sixth column selection transistors 226a and 226b of the column switches 210a and 210b, respectively. The second common sense amplifier pads CSP2a and CSP2b function as the third sense amplifier pad SP3b or the sixth sense amplifier pad SP6b depending on a voltage applied to the first common gates CG1a and CG1b and the second common gates CG2a and CG2b.

In an embodiment, the bit lines of the memory cell arrays MCA1 and MCA2 are arranged in the row direction D1 in a sequence that is symmetrically folded with respect to a midpoint between the first memory cell array MCA1 and the second memory cell array MCA2, and the first column switch 210a is rotated by 180 degrees with respect to the second column switch 210b. The fifth sense amplifier pad SP5a and the seventh sense amplifier pad SP7a of the first column switch 210a and the seventh sense amplifier pad SP7b and the fifth sense amplifier pad SP5b of the second column switch 210b may be arranged relative to each other.

In an embodiment, many of the sense amplifier pads of the column switch 210a, 210b have a rectangular planar structure, at least one of the sense amplifier pads SP5a, SP7a, SP5b, and SP7b located at the boundary of the first column switch 210a and the second column switch 210b has a polygonal structure that meets the first distance dn and the contact area.

For example, when the fifth sense amplifier pad SP5a of the first column switch 210a located in the lower row DR has a rectangular structure with a predetermined contact area, the seventh sense amplifier pad SP7b of the second column switch 210b is configured having a first segment disposed at 90 degrees from a second segment that meets the first distance dn and the contact area.

When the seventh sense amplifier pad SP7b of the second column switch 210b located in the upper row UR has a rectangular structure with a predetermined contact area, the fifth sense amplifier pad SP5a of the first column switch 210a is configured having a first segment disposed at 90 degrees from a second segment that meets the first distance dn and the contact area.

The fifth sense amplifier pad SP5a of the first column switch 210a and the fifth sense amplifier pad SP5b of the second column switch 210b may be diagonally arranged. The seventh sense amplifier pad SP7a of the first column switch 210a and the seventh sense amplifier pad SP7b of the second column switch 210b may be diagonally arranged.

Uniform contact areas of the sense amplifier pads SP0a through SP7a and SP0b through SP7b provide uniform electrical characteristics for the sense amplifiers SA0a through SA7a and SA0b through SA7b.

The sense amplifier pads SP0a through SP7a and SP0b through SP7b are electrically connected with the drains of the column selection transistors 220a through 227a and 220b through 227b and one conducting terminal of the sense amplifiers SA0a through SA7a and SA0b through SA7b in FIG. 2.

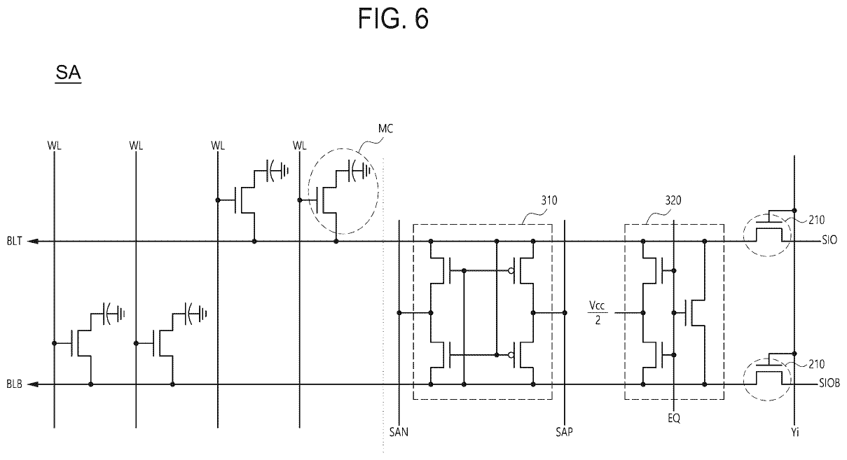

FIG. 6 is a circuit diagram illustrating a configuration of a semiconductor memory device including a sense amplifier in accordance with an embodiment.

Referring to FIG. 6, a sense amplifier SA is connected between a bit line BLT and a bit line bar BLB. The sense amplifier SA includes a latch 310 and an equalization circuit 320.

The column selection transistor 210 is connected between the equalization circuit 320 of the sense amplifier SA and segment I/O lines SIO and SIOB.

The sense amplifier pads SP0a through SP7a and SP0b through SP7b in FIG. 4 are electrically connected via conductive wiring (not shown) to the equalization circuit 320 of the corresponding sense amplifiers SA0a through SA7a and SA0b through SA7b.

In FIG. 6, reference numerals SAN and SAP indicate sense amplifier enable signal lines configured to operate the latch 310. Equalize signal lines EQ are configured to drive the equalization circuit 320. Circuit MC directs memory cells connected between the bit line BLT and the word line WL and between the bit line bar BLB and the word line WL.

Referring to FIG. 3 and FIG. 4, the sub-pattern 240 includes sub-interconnection patterns 241a through 241h and 242a through 242h.

The sub-interconnection patterns 241a through 241d are arranged on the first common gate CG1 of the first column switch 210a, and the sub-interconnection patterns 241e through 241h are arranged on the second common gate CG2 of the first column switch 210a.

The sub-interconnection patterns 242a through 242d are arranged on the first common gate CG1 of the second column switch 210b. The sub-interconnection patterns 242e through 242h re arranged on the second common gate CG2 of the second column switch 210b.

The sub-interconnection patterns 241a through 241d and 242a through 242d and the interconnection patterns 241e through 241h and 242e through 242h extend substantially parallel in the column direction D2 of the drawing, spaced apart by the same distance, for example, a first distance dn.

The edge-located first, third, fourth, and seventh sub-interconnection patterns 241a, 241d, 241e, 241h, 242a, 242d, 242e, 242h, 242a, 242d, 242e, and 242h are arranged with the column gate pads CP21a, CP21b, CP22a, and CP22b and the sense amplifier pads SP0a through SP7a and SP0b through SP7b to maintain the first distance dn. Thus, the lines in the first wiring structure are spaced apart and maintain the first distance dn.

In an embodiment, the first sub-interconnection patterns 241a and 242a connect the column switches 210a and 210b and corresponding first bit line BLT0 of the memory cell arrays MCA1 and MCA2 with the source S of the first transistors 220a and 220b of the column switches 210a and 210b, respectively. A first side of the first sub-interconnection pattern 241a and 242a is electrically connected with the first bit line BLT0 via the bit line contacts BLC. A second end of the first sub-interconnection pattern 241a and 242a is electrically connected with the source S of the first transistors 220a and 220b of the column switches 210a and 210b, respectively, via the first contact plug CT1.

The sub-interconnection patterns 241b through 242h connect, for example, the bit lines BLT1 through BLT7 of the column switches 210a and 210b and the corresponding memory cell arrays MCA1 and MCA2 and the sources S of the transistors 221a through 227b of the first and second column switches 210a and 210b, respectively.

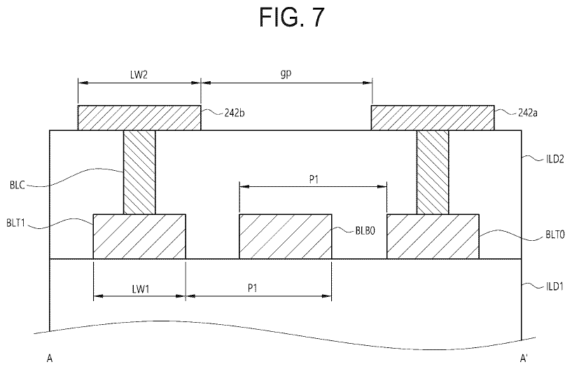

In an embodiment, a width and a pitch of each of the sub-interconnection patterns 241a through 241h and 242a through 242h may be substantially the same. The width of the sub-interconnection patterns 241a through 241h and 242a through 242h may be wider than the widths of the bit lines BLT0 through BLT7 and BLB0 through BLB7 in the first direction. Lack of electrical interference between the sub-interconnection patterns 241a through 241h and 242a through 242h and the bit lines BLT0 through BLT7 and BLB0 through BLB7 is described with reference to FIG. 7.

FIG. 7 is a cross-sectional view taken along line A-A′ in FIG. 4.

Referring to FIG. 7, the bit lines BLT0, BLB0, and BLT1 are formed with a predetermined pitch P1 on the first insulating layer ILD1. The second insulating layer ILD2 is formed on the first insulating layer ILD1.

A bit line contact BLC is formed in the second insulating layer ILD2. The bit line contact BLC contacts the bit lines BLT0 and BLT1. The bit line contact BLC in contact with the bit lines BLT0 and BLT1 is located at a first end of the bit lines BLT0, BLB0, and BLT1. Although not shown, a bit line contact in contact with the zeroth bit line bar BLB0 located between the bit lines BLT0 and BLT1 is located at a second end of the zeroth bit line bar BLB0.

A first metal layer is formed on the second insulating layer ILD2. The first metal layer is patterned to extend toward the second column switch 210b in contact with the bit line contact BLC, thereby forming a first sub-interconnection pattern 242a and a second sub-interconnection pattern 242b.

The integration density of the memory cell array regions MCA1 and MCA2 in FIG. 4 may be higher than the integration density of the column switches 210a and 210b. The widths LW2 of the sub-interconnection patterns 242a and 242b are larger than the widths LW1 of the bit lines BLT0, BLB0, and BLT1 located in the memory cell array regions MCA1 and MCA2.

Even though the widths LW2 of the sub-interconnection patterns 242a and 242b are relatively large, the sub-interconnection patterns 242a and 242b may be spaced apart by a distance or gap gp such that no other conductive patterns are located between the first sub-interconnection pattern 242a and the second sub-interconnection pattern 242b.

Although the first sub-interconnection pattern 242a and the second sub-interconnection pattern 242b and the zeroth bit line bar BLB0 are shown spaced apart by the first pitch P1, the first sub-interconnection pattern 242a, and the second sub-interconnection pattern 242b are not electrically affected by the zeroth bit line bar BLB0 due to the presence of the second insulating layer ILD2 between the sub-interconnection patterns 242a and 242b and the zeroth bit line bar BLB0.

As a result, the first wiring structures located on a region associated with the first column switch 210a and a region associated with the second column switch 210b may be arranged to meet the first distance dn.

A dummy area DA having a distance dw greater than the first distance dn may be generated at the boundary between the column switches 210a and 210b. The dummy area DA of an embodiment is narrower than a dummy area generated between conventional column switches arranged in succession and having the same structure.

The first wiring structure of an embodiment further includes a dummy pattern DP formed in the dummy area DA. The dummy pattern DP is arranged at the boundary between the first column switch 210a and the second column switch 210b, for example, between the fifth sense amplifier pad SP5a and the seventh sense amplifier pad SP7a of the first column switch 210a and the seventh sense amplifier pad SP7b and fifth sense amplifier pad SP5b of the second column switch 210b. The dummy pattern DP of an embodiment is connected to first wiring structures, such as the first column gate pads CP21a and CP21b, and the second column gate pads CP22a and CP22b, the zeroth to seventh sense amplifier pads SP0a through SP7a and SP0b through SP7b, and the zeroth to seventh sub-interconnection patterns 241a through 241h and 242a through 242h, each of which is configured to maintain the first distance dn from the dummy pattern DP.

In an embodiment, the dummy pattern DP is arranged between the seventh sub-interconnection pattern 241h of the first column switch 210a and the seventh sense amplifier pad SP7a of the first column switch 210a, between the seventh sense amplifier pad SP7a of the first column switch 210a and the fifth sense amplifier pad SP5a of the first column switch 210a, between the seventh sense amplifier pad SP7b of the second column switch 210b and the fifth sense amplifier pad SP5b of the second column switch 210b, between the seventh sense amplifier pad SP7a of the first column switch 210a and the seventh sense amplifier pad SP7b of the second column switch 210b, and between the seventh sub-interconnection wiring 242h of the second column switch 210b and the seventh sense amplifier pad SP7b of the second column switch 210b.

As the dummy pattern DP is formed, spacing between the dummy pattern DP and the seventh sub-interconnection pattern 241h of the first column switch 210a, spacing between the dummy pattern DP and the seventh sense amplifier pad SP7a of the first column switch 210a, spacing between the dummy pattern DP and the fifth sense amplifier pad SP5a of the first column switch 210a, and spacing between the dummy pattern DP and the seventh sense amplifier pad SP7b of the second column switch 210b, spacing between the dummy pattern DP and the seventh sub-interconnection wiring 242h of the second column switch 210b, and spacing between the dummy pattern DP and the fifth sense amplifier pad SP5b of the second column switch 210b may be maintained within the first distance dn.

The dummy pattern DP may have varying widths to meet the first distance dn between the dummy pattern DP and the seventh sub-interconnection pattern 241h of the first column switch 210a, between the dummy pattern DP and the seventh sense amplifier pad SP7a of the first column switch 210a, between the dummy pattern DP and the fifth sense amplifier pad SP5a of the first column switch 210a, between the dummy pattern DP and the seventh sense amplifier pad SP7b of the second column switch 210b, between the dummy pattern DP and the seventh sub-interconnection wiring 242h of the second column switch 210b, and between the dummy pattern DP and the fifth sense amplifier pad SP5b of the second column switch 210b.

By the arrangement of the first column switch 210a and the second column switch 210b as shown, for example, in FIG. 4, one dummy pattern DP is arranged as a first wiring structure without a dummy gate the dummy region DA between the first column switch 210a and the second column switch 210b. Accordingly, two dummy bit lines DBL1 and DBL2 are disposed between the first and second memory cell arrays MCA1 and MCA2 corresponding to the dummy region DA. Thus, the integration margin of the memory cell array may be improved.

Referring to FIG. 5, a third insulating layer (not shown) is formed on the second insulating layer in which the first column gate pads CP21a and CP21b, the second column gate pads CP22a and CP22b, the sense amplifier pads SP0a through SP7a and SP0b through SP7b and the sub-pattern 240 are formed.

Via contacts VC0a, VC0b, VC1a, VC4a, VC1b, VC4b, VC2a, VC2b, VC3a, VC6a, VC3b, VC6b, V5a, V5b, V7a, V7b, VYi1, VYi2, VYi3, and VYi4, which contact the amplifier pads SP0a through SP7a and SP0b through SP7b, first column gate pads CP21a and CP21b, and second column gate pads CP22a and CP22b are formed in the third insulating layer.

A second wiring structure is formed on the third insulating layer in which the via contacts VC0a, VC0b, VC1a, VC4a, VC1b, VC4b, VC2a, VC2b, VC3a, VC6a, VC3b, VC6b, V5a, V5b, V7a, V7b, VYi1, VYi2, VYi3, and VYi4 are formed.

For example, the second wiring structure may include the segment I/O lines SIO<0:3> and the zeroth column selection pad YiP1 to the fourth column selection pad YiP4 as data I/O lines. For example, the segment I/O lines SIO<0:3> and the column selection pads YiP1 through YiP4 may include the same metal. The column selection pads may be referred to simply as selection pads, such as a first selection pad and a second selection pad, and need not associate with a column.

In an embodiment, the zeroth segment I/O line SIO<0> of the first column switch 210a extends in the row direction D1 while contacting the via contact VC0a that contacts the zeroth sense amplifier pad SP0a and the via contact VC5a that contacts the fifth sense amplifier pad SP5a. The zeroth segment I/O line SIO<0> of the second column switch extends in the row direction D1 while contacting the via contact VC0b that contacts the zeroth sense amplifier pad SP0b and the via contact VC5b that contacts the fifth sense amplifier pad SP5b. The zeroth segment I/O line SIO<0> of the first column switch 210a and the zeroth segment I/O line SIO<0> of the second column switch 210b may be electrically connected through a subsequent metal interconnection process.

The first segment I/O line SIO<1> of the first column switch 210a extends in the row direction D1 while contacting the via contacts VC1a, VC4a that contact the first common sense amplifier pad CSP1a, referred to as the first sense amplifier pad SP1a and the fourth sense amplifier pad SP4a. The first segment I/O line SIO<1> of the second column switch 210b extends in the row direction D1 while contacting the via contacts VC1b, VC4b that contact the first common sense amplifier pad CSP1b, referred to as the first sense amplifier pad SP1b and fourth sense amplifier pad SP4b. The first segment I/O line SIO<1> of the first column switch 210a and the first segment I/O line SIO<1> of the second column switch 210b may be electrically connected through a subsequent metal interconnection process.

The second segment I/O line SIO<2> of the first column switch 210a extends in the row direction D1 while contacting the via contact VC2a that contacts the second sense amplifier pad SP2a and the via contact VC7a that contacts the seventh sense amplifier pad SP7a. The second segment I/O line SIO<2> of the second column switch 210b extends in the row direction D1 while contacting the via contact VC2b in contact with the second sense amplifier pad SP2b and the via contact VC7b in contact with the seventh sense amplifier pad SP7b. The second segment I/O line SIO<2> of the first column switch 210a and the second segment I/O line SIO<2> of the second column switch 210b may be electrically connected through a subsequent metal interconnection process.

The third segment I/O line SIO<3> of the first column switch 210a extends in the row direction D1 while contacting the via contacts VC3a, VC6a that contact the second common sense amplifier pad CSP2a, referred to as the third sense amplifier pad SP3a and the sixth sense amplifier pad SP6a. The second segment I/O line SIO<2> of the second column switch 210b extends in the row direction D1 while contacting the via contacts VC3b, VC6b that contact the second common sense amplifier pad CSP2b, referred to as the third sense amplifier pad SP3b and the sixth sense amplifier pad SP6b. The third segment I/O line SIO<3> of the first column switch 210a and the third segment I/O line SIO<2> of the second column switch 210b may be electrically connected through a subsequent metal interconnection process.

Because the column selection transistors 220a through 227a of the first column switch 210a are rotated 180 degrees with respect to the column selection transistors 220b through 227b of the second column switch 210b, the segment I/O lines SIO<0:3> of the first column switch 210a may also be rotated 180 degrees with respect to the segment I/O lines SIO<0:3> of the second column switch 210b.

The column selection transistors 220a through 227a of the first column switch 210a are rotated 180 degrees with respect to the column selection transistors 220b through 227b of the second column switch 210b and may be arranged in a 2×4 matrix. The segment I/O lines SIO<0> and SIO<1> of the first column switch 210a are arranged in the lower row DR, and the segment I/O lines SIO<2> and SIO<3> are arranged in the upper row UR. The segment I/O lines SIO<0> and SIO<1> of the second column switch 210b are arranged in the upper row UR, and the segment I/O lines SIO<2> and SIO<3> are arranged in the lower row DR.

The widths LW3 of the segment I/O lines SIO<0:3> of the first column switch 210a and the widths LW3 of the segment I/O lines SIO<0:3> of the second column switch 210b may be substantially the same.

The widths LW3 of the segment I/O lines SIO<0:3> of the first column switch 210a and the widths LW3 of the segment I/O lines SIO<0:3> of the second column switch 210b may be wider than the widths LW3 of each of the sub-interconnection patterns 241a through 241h and 242a through 242h.

The first column selection pad Yi1P contacts the via contact VYi1 that is arranged on the first column gate pad CP21a of the first switch 210a. The via contact VYi1 electrically connects the first column gate pad CP21a of the first switch 210a and the first column selection pad Yi1P. For example, the area of the first column selection pad Yi1P is larger than the area of the first column gate pad CP21a. The first column selection pad Yi1P is electrically connected with the first column selection signal line Yi1, such as shown in FIG. 2.

The second column selection pad Yi2P contacts the via contact VYi2 that is arranged on the second column gate pad CP21a of the first switch 210a. The via contact VYi2 electrically connects the second column gate pad CP22a of the first switch 210a with the second column selection pad Yi2P. For example, the area of the second column selection pad Yi2P is larger than the area of the second column gate pad CP22a. The second column selection pad Yi2P is electrically connected with the second column selection signal line Yi2, such as shown in FIG. 2.

The third column selection pad Yi3P contacts the via contact VYi3 that is arranged on the first column gate pad CP21b of the second switch 210b. The via contact VYi3 electrically connects the first column gate pad CP21b of the second switch 210b with the third column selection pad Yi3P. For example, the area of the third column selection pad Yi3P is larger than the area of the first column gate pad CP21b. The third column selection pad Yi3P is electrically connected with the third column selection signal line Yi3, such as shown in FIG. 2.

The fourth column selection pad Yi4P contacts the via contact VYi4 that is arranged on the second column gate pad CP22b of the second switch 210b. The via contact VYi4 electrically connects the second column gate pad CP22b of the second switch 210b with the fourth column selection pad Yi4P. For example, the area of the fourth column selection pad Yi4P is larger than the area of the second column gate pad CP22b. The fourth column selection pad Yi4P is electrically connected with the third column selection signal line Yi4, such as shown in FIG. 2.

When the column selection transistors 220a through 227a of the first column switch 210a are rotated 180 degrees with respect to the column selection transistors 220b through 227b of the second column switch 210b, a sufficient distance between consecutively arranged contacts VC0a, VC0b, VC1a, VC4a, VC1b, VC4b, VC2a, VC2b, VC3a, VC6a, VC3b, VC6b, V5a, V5b, V7a, V7b, VYi1, VYi2, VYi3, and VYi4 may be established.

Because the first column switch 210a is rotated 180 degrees with respect to the second column switch 210b, the column selection pads Yi1P through Yi4P may be arranged according to a predetermined distance between the lower row DR and the upper row UR, for example, based on the boundaries of the column switches 210a and 210b. Each of the column selection pads Yi1P through Yi4P are spaced apart from the nearest zero segment I/O line SIO<0> and the nearest third segment I/O line SIO<3> by a second distance dm. The second distance dm may be a distance over which electrical interference is reduced or eliminated between the conductive lines arranged on the third insulating interlayer.

The first column selection pad Yi1P is rotated 180 degrees with respect to the third column selection pad Yi3P and is equally spaced from the nearest segment lines SIO<0> and SIO<3>. The second column selection pad Yi2P is rotated 180 degrees with respect to the fourth column selection pad Yi4P and is equally spaced from the nearest segment lines SIO<0:3>.

The column selection transistors 220a through 227a and the common gate contacts CG1a, CG2a of the first column switch 210a are rotated 180 degrees with respect to the column selection transistors 220b through 227b and the common gate contacts CG1b, CG2b of the second column switch 210b, which reduces the area of the dummy region, and may prevent unevenly clustering contacts and vias in a particular region.

According to an embodiment, the column selection transistors of the first column switch are rotated 180 degrees with respect to the column transistors of the second column switch, and the column selection transistors of the first column switch and the column transistors of the second column switch are arranged consecutively in the row direction. Accordingly, a sufficient distance between the gate contacts of the column selection transistors of the first column switch and the gate contacts of the column selection transistors of the second column switch is obtained without providing separate or additional spacing between the first column switch and the second column switch.

A reduced quantity of dummy patterns may be utilized between the first column switch and the second column switch by arranging the first column switch and the second column switch with a reduced spacing.

Because the quantity of dummy bit lines arranged between the memory cell arrays may be proportional to the quantity of the dummy patterns between the first column switch and the second column switch, the quantity of dummy bit lines may be reduced. The area of the memory cell array may be expanded, and integration density may be improved.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

What is claimed is:

1. A semiconductor integrated circuit device comprising:
a first memory cell array and a second memory cell array each including a plurality of word lines extending in a first direction, a plurality of bit lines extending in a second direction perpendicular to the first direction, and a plurality of memory cells connected between the plurality of word lines and the plurality of bit lines;
a first switch configured to selectively connect a first plurality of sense amplifiers that are connected to bit lines among the plurality of bit lines of the first memory cell array with data input/output (I/O) lines; and
a second switch configured to selectively connect a second plurality of sense amplifiers that are connected to bit lines of the plurality of bit lines of the second memory cell array with the data I/O lines;
wherein the first memory cell array and the second memory cell array are spaced apart in the first direction; and
wherein the first switch is rotated 180 degrees with respect to the second switch.

2. The semiconductor integrated circuit device of claim 1, wherein each of the first switch and the second switch comprises a plurality of selection transistors; and
wherein the plurality of selection transistors of the first switch are rotated 180 degrees with respect to the plurality of selection transistors of the second switch.

3. The semiconductor integrated circuit device of claim 1, wherein each of the first switch and the second switch comprises a plurality of selection transistors;
wherein each of the plurality of selection transistors comprises:
an active region;
a selection gate disposed at least partially in the active region;
a source, formed in the active region, corresponding to a first side of the gate; and
a drain, formed in the active region, corresponding to a second side of the gate;
wherein selection gate of a first subset of the plurality of selection transistors are interconnected to form a first common gate; and
wherein selection gates of a second subset of the plurality of selection transistors are interconnected to form a second common gate.

4. The semiconductor integrated circuit device of claim 3, wherein the first common gate of the first switch receives a first selection signal, wherein the second common gate of the first switch receives a second selection signal, wherein the first common gate of the second switch receives a third selection signal, and wherein the second common gate of the second switch receives a fourth selection signal.

5. The semiconductor integrated circuit device of claim 4, wherein the first selection signal, the second selection signal, the third selection signal, and the fourth selection signal are enabled at different times.

6. The semiconductor integrated circuit device of claim 3, wherein the active regions of the first subset of the plurality of selection transistors controlled by the first common gate are isolated from each other, and wherein the active regions of the second subset of the plurality of selection transistors controlled by the second common gate are isolated from each other.

7. The semiconductor integrated circuit device of claim 6, wherein consecutive active regions arranged in the first direction contact each other to share drains.

8. The semiconductor integrated circuit device of claim 3,
wherein the first switch further comprise a first gate contact connected to a first side of the first common gate of the first switch and a second gate contact connected to a first side of the second common gate of the first switch;
wherein the second switch further comprise a first gate contact connected to a second side of the first common gate of the second switch and a second gate contact connected to a second side of the second common gate of the second switch; and
wherein the first gate contact and the second gate contact of the first switch are rotated 180 degrees with respect to the first gate contact and the second gate contact of the second switch.

9. The semiconductor integrated circuit device of claim 8,
wherein the first switch further comprises a first gate pad arranged on the first gate contact of the first switch, and a second gate pad arranged on the second gate contact of the first switch;
wherein the second switch further comprises a first column gate pad arranged on the first gate contact of the second switch and a second column gate pad arranged on the second gate contact of the second switch; and
wherein areas of the first gate pad and the second column gate pads of the first switch and the second switch are larger than areas of the first gate contact and the second gate contact.

10. The semiconductor integrated circuit device of claim 9,
wherein the first switch further comprises a plurality of sub-interconnection patterns connecting the sources of the plurality of selection transistors of the first switch with the bit lines of the first memory cell array; and
wherein the second switch further comprises a plurality of sub-interconnection patterns connecting the sources of the plurality of selection transistors of the second switch with the bit lines of the second memory cell array.

11. The semiconductor integrated circuit device of claim 10,
wherein the first switch further comprises a plurality of sense amplifier pads connecting the drains of the plurality of selection transistors of the first switch with the plurality of sense amplifiers of the first sense amplifier array; and
wherein the second switch further comprises a plurality of sense amplifier pads each connecting the drains of the plurality of selection transistors of the second switch with the plurality of sense amplifiers of the second sense amplifier array.

12. The semiconductor integrated circuit device of claim 11,
wherein the first gate pad and the second gate pad of the first switch and the second switch, the plurality of sub-interconnection patterns, and the plurality of sense amplifier pads are located on one plane; and
wherein the first gate pad and the second gate pad near the first switch and the second switch, the plurality of sub-interconnection patterns, the plurality of sub-interconnection patterns near the first switch and the second switch, and the plurality of sub-interconnection patterns near the plurality of sense amplifier pads maintain a first distance.

13. The semiconductor integrated circuit device of claim 12, further comprising a dummy pattern arranged between the first switch and the second switch;
Wherein each of spacing between a first side of the dummy pattern and an edge of the first switch closest to the dummy pattern and spacing between a second side of the dummy pattern and an edge of the second switch closest to the dummy pattern is the first distance; and
wherein at least one dummy bit line, which has a width less than a width of the dummy pattern, is arranged, based on the dummy pattern, at a boundary of the first memory cell array and the second memory cell array.

14. The semiconductor integrated circuit device of claim 10,
wherein each of the first switch and the second switch further comprise a first selection pad arranged on the first gate pad, and a second selection pad arranged on the second gate pad; and
wherein the first selection pad has a larger area than the first gate contact pad, and the second selection pad has a larger area than the second gate contact pad.

15. The semiconductor integrated circuit device of claim 14,
wherein the data I/O lines comprise a plurality of segment I/O lines arranged on the first switch and the second switch; and
wherein each of the plurality of segment I/O lines is commonly connected with the sense amplifier pad connected to a selection transistor of the first subset of the plurality of selection transistors, and the sense amplifier pad connected to a selection transistor of the second subset of the plurality of selection transistors.

16. The semiconductor integrated circuit device of claim 15,
wherein the plurality of segment I/O lines extend substantially parallel in the first direction; and
wherein spacing between the plurality of segment I/O lines and spacing between segment I/O lines closest to the first selection pad or the second selection pad are a second distance.

17. The semiconductor integrated circuit device of claim 1, wherein the plurality of bit lines of the first memory cell array and the plurality of bit lines of the second memory cell array are arranged symmetrically with respect to a boundary of the first and second memory cell arrays.

18. A semiconductor integrated circuit device comprising:
a first memory cell array, a second memory cell array, a third memory cell array, and a fourth memory cell array arranged in a matrix in a first direction and a second direction;
a first selection block arranged between the first memory cell array and the third memory cell array arranged consecutively in the second direction; and
a second selection block arranged between the second memory cell array and the fourth memory cell array arranged consecutively in the second direction;
wherein the first selection block comprises a plurality of sense amplifiers connecting a first subset of bit lines of the first memory cell array with a first subset of bit lines of the third memory cell array, and a first switch including a plurality of selection transistors connected to the plurality of sense amplifiers that transmit a signal from a bit line selected from the first memory cell array and the third memory cell array to one of a plurality of input and output signal lines in response to a selection signal;
wherein the second selection block comprises a plurality of sense amplifiers connecting a first subset of bit lines of the second memory cell array with a first subset of bit lines of the fourth memory cell array, and a second switch including a plurality of selection transistors, the plurality of selection transistors connected to the plurality of sense amplifiers to transmit a signal from a bit line selected from the second memory cell array and the fourth memory cell array to one of a plurality of input/output lines in response to a selection signal; and
wherein the plurality of selection transistors of the first switch is rotated 180 degrees with respect to the plurality of selection transistors of the second switch.

19. The semiconductor integrated circuit device of claim 18,
wherein each of the first switch and the second switch comprises a plurality of selection transistors;
wherein gates of a first subset of the plurality of selection transistors of the first switch receive a first selection signal in common via a first gate contact;
wherein gates of a second subset of the plurality of selection transistors of the first switch receive a second selection signal in common via a second gate contact;
wherein gates of the first subset of the plurality of selection transistors of the second column switch receive a third selection signal in common via a third gate contact;
wherein gates of the second subset of the plurality of selection transistors of the second switch are configured to receive a fourth selection signal in common via the fourth gate contact; and
wherein the first selection signal, the second selection signal, the third selection signal, and the fourth selection signal are enabled at different times.

20. The semiconductor integrated circuit device of claim 19,
wherein each of the first switch and the second switch comprises first connections between the gates of the first subset of the plurality of selection transistors and second connections between the gates of the second subset of the plurality of selection transistors,
wherein the first gate contact is located on a first side of the first connection of the first switch, the second gate contact is located on a first side of the second connection of the first switch, the third gate contact is located on a second side of the first connection of the second switch, and the fourth gate contact is located on a second side of the second connection of the second switch;
wherein the first gate contact and the second gate contact are arranged closer to the third memory cell array than to the first memory cell array; and
wherein the third gate contact and the fourth gate contact are arranged closer to the second memory cell array than to the fourth memory cell array.

21. The semiconductor integrated circuit device of claim 19,
wherein a third subset of the plurality of selection transistors of the first switch are arranged closer to the third memory cell array than to the first memory cell array, and a fourth subset of the plurality of selection transistors are arranged closer to the first memory cell array than to the third memory cell array;
wherein the third subset of the plurality of selection transistors of the first column switch are arranged closer to the first memory cell array than to the third memory cell array, and the fourth subset of the plurality of selection transistors are arranged closer to the third memory cell array than to the first memory cell array.

22. A semiconductor integrated circuit device comprising:
a plurality of switches, each of the switches including a plurality of selection transistors configured to selectively connect a plurality of sense amplifiers that are connected to a plurality of bit lines with a plurality of data input/output lines based on selection signals;
wherein the plurality of selection transistors of a first switch is rotated 180 degrees with respect to the plurality of selection transistors of a second switch, and the plurality of selection transistors of the first switch is spaced apart from the plurality of selection transistors of the second switch in a first direction.

23. The semiconductor integrated circuit device of claim 22,
wherein the first switch comprises a first common gate configured to control a first subset of the plurality of selection transistors and a second common gate configured to control a second subset of the plurality of selection transistors; and
wherein the second column switch comprises a third common gate configured to control a third subset of the plurality of selection transistors and a fourth common gate configured to control a fourth subset of the plurality of selection transistors.

24. The semiconductor integrated circuit device of claim 23, further comprising:
a first gate contact configured to transmit a first selection signal to the first common gate;
a second gate contact configured to transmit a second selection signal to the second common gate;
a third gate contact configured to transmit a third selection signal to the third common gate; and
a fourth contact gate configured to transmit a fourth selection signal to the fourth common gate;
wherein a first line on which the first gate contact and the second gate contact are located is parallel to and separated by a distance from a second line on which the third gate contact and the fourth gate contact are located.

25. The semiconductor integrated circuit device of claim 22, wherein the first direction is orthogonal to a direction in which the bit line extends.
